(19) United States
(12) Patent Application Publication
(10) Pub. No.: US 2022/0093435 A1
(43) Pub. Date: Mar. 24, 2022

(54) SUBSTRATE PROCESSING APPARATUS, SUBSTRATE RETAINER AND METHOD OF MANUFACTURING SEMICONDUCTOR DEVICE

(71) Applicant: KOKUSAI ELECTRIC CORPORATION, Tokyo (JP)

(72) Inventors: Kenji SHINOZAKI, Toyama (JP); Yoshihiko YANAGISAWA, Toyama (JP); Noriaki MICHITA, Toyama (JP); Shinya SASAKI, Toyama (JP); Shuhei SAIDO, Toyama (JP); Tetsuo YAMAMOTO, Toyama (JP)

(73) Assignee: KOKUSAI ELECTRIC CORPORATION, Tokyo (JP)

(21) Appl. No.: 17/475,535

(22) Filed: Sep. 15, 2021

(30) Foreign Application Priority Data
Sep. 18, 2020 (JP) 2020-157917

(51) Int. Cl. H01L 21/673; H01L 21/263; H05B 6/80

(52) U.S. Cl. CPC H01L 21/67323; H05B 6/80; H01L 21/2636

(57) ABSTRACT

Described herein is a technique capable of uniformly processing a substrate. According to one aspect of the technique, there is provided a substrate processing apparatus including: a process chamber in which a substrate is processed; a microwave generator configured to supply a microwave to the process chamber to perform a heat treatment on the substrate; a substrate retainer configured to accommodate the substrate and a heat retainer provided above the substrate and retaining a temperature of the substrate heated by the microwave; and a first ring plate provided on an outer circumference of the heat retainer and whose outer diameter is greater than that of the substrate.

### CROSS-REFERENCE TO RELATED PATENT APPLICATION

This non-provisional U.S. patent application claims priority under 35 U.S.C. § 119 of Japanese Patent Application No. 2020-157917, filed on Sep. 18, 2020, in the Japanese Patent Office, the entire contents of which are hereby incorporated by reference.

### BACKGROUND

### 1. Field

The present disclosure relates to a substrate processing apparatus, a substrate retainer and a method of manufacturing a semiconductor device.

### 2. Related Art

As a part of manufacturing processes of a semiconductor device, a modification process such as an annealing process may be performed. For example, the annealing process is performed by heating a substrate in a process chamber by using a heater to change a composition and a crystal structure of a film formed on a surface of the substrate or to restore a defect such as a crystal defect in the film. Recently, the semiconductor device is integrated at a high density and remarkably miniaturized. As a result, it is preferable that the modification process is performed to a high density substrate on which a pattern is formed with a high aspect ratio. As the modification process capable of modifying the high density substrate, a heat treatment using a microwave (also referred to as an “electromagnetic wave”) may be performed.

However, in a conventional process using the microwave, the heat may escape outward in a radial direction of a component such as the substrate in a process chamber, and the heat may be trapped inward in the radial direction of the component. As a result, it may be difficult to uniformly modify the substrate.

### SUMMARY

Described herein is a technique capable of uniformly processing a substrate.

According to one aspect of the technique of the present disclosure, there is provided a substrate processing apparatus including: a process chamber in which a substrate is processed; a microwave generator configured to supply a microwave to the process chamber to perform a heat treatment on the substrate; a substrate retainer configured to accommodate the substrate and a heat retainer provided above the substrate and retaining a temperature of the substrate heated by the microwave; and a first ring plate provided on an outer circumference of the heat retainer and whose outer diameter is greater than that of the substrate.

### BRIEF DESCRIPTION OF THE DRAWINGS

FIG. 1 is a diagram schematically illustrating a vertical cross-section of a substrate processing apparatus preferably used in one or more embodiments described herein.

FIG. 2 is a diagram schematically illustrating a horizontal cross-section of the substrate processing apparatus preferably used in the embodiments described herein.

FIG. 3 is a diagram schematically illustrating a vertical cross-section of a single wafer type process furnace of the substrate processing apparatus preferably used in the embodiments described herein.

FIG. 4 is a block diagram schematically illustrating a configuration of a controller and related components of the substrate processing apparatus preferably used in the embodiments described herein.

FIG. 5 is a flow chart schematically illustrating a substrate processing according to the embodiments described herein.

FIG. 6 is a diagram schematically illustrating a partial perspective view of a substrate retainer (boat) preferably used in the embodiments described herein.

FIG. 7A is a diagram schematically illustrating a state in which a quartz plate is supported by the substrate retainer preferably used in the embodiments described herein when viewed from above, and FIG. 7B is a diagram schematically illustrating the state in which the quartz plate is supported by the substrate retainer preferably used in the embodiments described herein when viewed from a side thereof.

FIGS. 8A and 8B are diagrams schematically illustrating a cross-section of a retaining structure of supporting a first ring plate in a second ring plate in the quartz plate preferably used in the embodiments described herein.

FIGS. 9A and 9B are diagrams schematically illustrating a cross-section of a modified example of the retaining structure of supporting the first ring plate in the second ring plate in the quartz plate preferably used in the embodiments described herein.

FIG. 10A is a diagram schematically illustrating a state in which a quartz plate preferably used in a first modified example of the embodiments described herein is supported by the substrate retainer when viewed from above, and FIG. 10B is a diagram schematically illustrating the state in which the quartz plate preferably used in the first modified example of the embodiments described herein is supported by the substrate retainer when viewed from a side thereof.

FIG. 11A is a diagram schematically illustrating a state in which a quartz plate preferably used in a second modified example of the embodiments described herein is supported by the substrate retainer when viewed from above, and FIG. 11B is a diagram schematically illustrating the state in which the quartz plate preferably used in the second modified example of the embodiments described herein is supported by the substrate retainer when viewed from a side thereof.

FIG. 12 is a diagram schematically illustrating a cross-section of a modified example of the retaining structure of supporting the first ring plate in the second ring plate in the quartz plate preferably used in the second modified example of the embodiments described herein.

FIG. 13A is a diagram schematically illustrating a state in which a quartz plate preferably used in a third modified example of the embodiments described herein is supported by the substrate retainer when viewed from above, and FIG. 13B is a diagram schematically illustrating the state in which the quartz plate preferably used in the third modified example of the embodiments described herein is supported by the substrate retainer when viewed from a side thereof.

### DETAILED DESCRIPTION

### Embodiments

Hereinafter, one or more embodiments (also simply referred to as “embodiments”) according to the technique of the present disclosure will be described with reference to the drawings. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

### (1) Configuration of Substrate Processing Apparatus

The present embodiments will be described by way of an example in which a substrate processing apparatus 100 is configured as a single wafer type heat treatment apparatus capable of performing various kinds of heat treatments (also referred to as “heat treatment processes”) on a wafer 200 or a plurality of wafers 200. The plurality of wafers 200 may also be simply referred to as wafers 200 simultaneously. For example, in the present embodiments, the substrate processing apparatus 100 is configured as an apparatus capable of performing a modification process such as an annealing process using an electromagnetic wave described later. In the substrate processing apparatus 100 according to the present embodiments, a FOUP (Front Opening Unified Pod, hereinafter, also referred to as a “pod”) 110 is used as a storage container (also referred to as a “carrier”) in which the wafer 200 serving as a substrate is accommodated. The pod 110 is also used as a transfer container when the wafer 200 is transferred between various substrate processing apparatuses including the substrate processing apparatus 100.

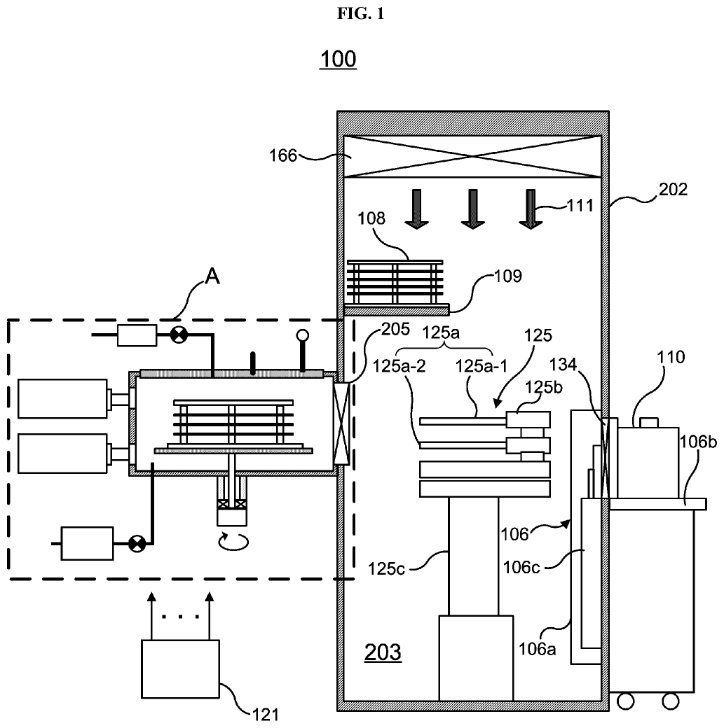

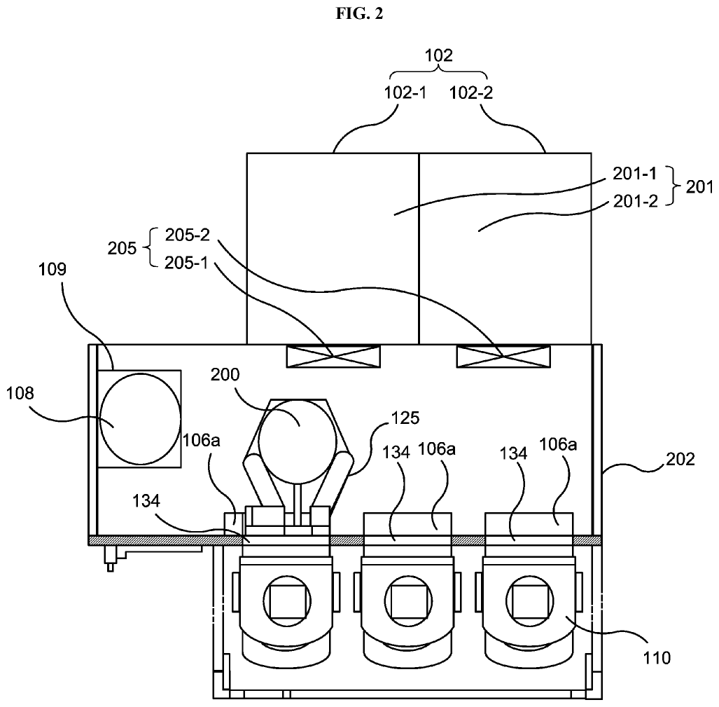

As shown in FIGS. 1 and 2, the substrate processing apparatus 100 includes: a transfer housing 202 with a transfer chamber (also referred to as a “transfer region”) 203 provided therein; and cases 102-1 and 102-2 with process chambers 201-1 and 201-2 provided therein, respectively. The wafer 200 is transferred into or out of the transfer chamber 203. The cases 102-1 and 102-2 are provided on a side wall of the transfer housing 202. The cases 102-1 and 102-2 serve as a process vessel which will be described later. For example, the wafers 200 are processed in the process chambers 201-1 and 201-2, respectively. A loading port structure (also referred as an “LP”) 106 serving as a pod opening/closing structure capable of opening and closing a lid of the pod 110 so as to transfer the wafer 200 into and out of the transfer chamber 203 is provided at a front side of the transfer housing 202 of the transfer chamber 203. That is, the loading port structure 106 is shown in a right portion of FIG. 1 (a lower portion of FIG. 2). The loading port structure 106 includes a housing 106a, a stage 106b and an opener 106c. The stage 106b is configured to transfer the pod 110 to a position close to a substrate loading/unloading port 134 provided in front of the transfer housing 202 of the transfer chamber 203 while the pod 110 is placed on the stage 106b. The opener 106c is configured to open and close the lid (not shown) provided in the pod 110. The transfer housing 202 includes a purge gas circulation structure provided with a cleaning structure 166. The purge gas circulation structure is configured to circulate a purge gas such as N₂ gas in the transfer chamber 203.

Gate valves 205-1 and 205-2 capable of opening and closing the process chambers 201-1 and 201-2 are provided at a rear side of the transfer housing 202 of the transfer chamber 203, respectively. That is, the gate valves 205-1 and 205-2 are shown in a left portion of FIG. 1 (an upper portion of FIG. 2). A transfer device 125 serving as a substrate transfer structure (also referred to as a “substrate transfer robot”) capable of transferring the wafer 200 is provided in the transfer chamber 203. The transfer device 125 may include: a plurality of tweezers (also referred to as “arms”) 125a-1 and 125a-2 serving as a placement structure on which the wafer 200 is placed; a transfer structure 125b capable of rotating or linearly moving each of the plurality of tweezers 125a-1 and 125a-2 in a horizontal direction; and a transfer structure elevator 125c capable of elevating and lowering the transfer structure 125b. By consecutive operations of the plurality of tweezers 125a-1 and 125a-2, the transfer structure 125b and the transfer structure elevator 125c, it is possible to charge (load) or discharge (unload) the wafer 200 into or out of a component such as a boat 217 serving as a substrate retainer which will be described later and the pod 110. Hereinafter, unless they need to be distinguished separately, the cases 102-1 and 102-2 may be collectively or individually referred to as a case 102, the process chambers 201-1 and 201-2 may be collectively or individually referred to as a process chamber 201, the gate valves 205-1 and 205-2 may be collectively or individually referred to as a gate valve 205 and the plurality of tweezers 125a-1 and 125a-2 may be collectively or individually referred to as “tweezers” 125a.

As shown in FIG. 1, in a space above the transfer chamber 203 and below the cleaning structure 166, a wafer support 108 is provided on a wafer support table 109. The processed wafer 200 may be placed on the wafer support 108 until it is sufficiently cooled. A structure of the wafer support 108 is similar to that of the boat 217 serving as the substrate retainer which will be described later. The wafer support 108 is configured to support (hold) the wafers 200 in a horizontal orientation in a vertically multistage manner by a plurality of wafer supporting grooves (wafer supporting portions). Since the wafer support 108 and the wafer support table 109 are provided above the substrate loading/unloading port 134 and the gate valve 205, the wafer support 108 and the wafer support table 109 deviate from the line of movement of the wafer 200 being transferred from the pod 110 to the process chamber 201 by the transfer device 125. Therefore, it is possible to cool the processed wafer 200 without reducing the throughput of a wafer processing (also referred to as a “substrate processing”). Hereinafter, the wafer support 108 and the wafer support table 109 may be collectively referred to as a “cooling area” or a “cooling region”.

According to the present embodiments, an inner pressure of the pod 110, an inner pressure of the transfer chamber 203 and an inner pressure of the process chamber 201 are controlled (adjusted) to be equal to or higher than the atmospheric pressure by about 10 Pa to 200 Pa (gauge pressure). It is preferable that the inner pressure of the transfer chamber 203 is higher than the inner pressure of the process chamber 201, and the inner pressure of the process chamber 201 is higher than the inner pressure of the pod 110.

### Process Furnace

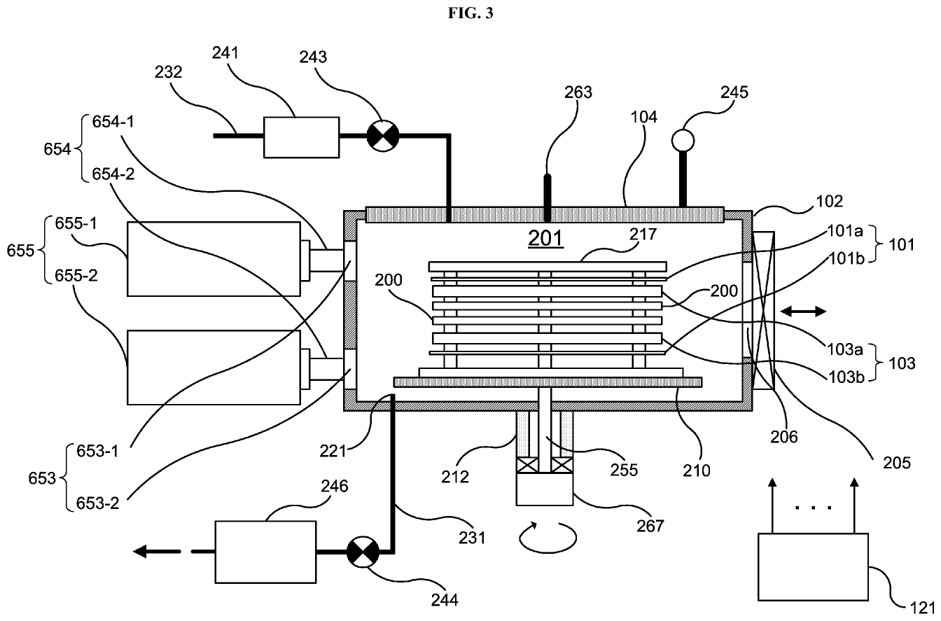

A process furnace provided with a substrate processing structure as shown in FIG. 3 is disposed in a region “A” surrounded by a broken line in FIG. 1. As shown in FIG. 2, although a plurality of process furnaces are provided according to the present embodiments, only one process furnace will be described and the detailed descriptions of the other process furnaces will be omitted since the configurations of the plurality of process furnaces are the same.

As shown in FIG. 3, the process furnace according to the present embodiments includes the case 102 serving as a cavity (process vessel) made of a material such as a metal capable of reflecting the electromagnetic wave. A cap flange (closing plate) 104 made of a metal material is in contact with the case 102 to close (seal) a ceiling surface of the case 102 via an O-ring (not shown) serving as a seal. The process chamber 201 in which the wafer 200 such as a silicon wafer is processed is mainly constituted by an inner space enclosed by the case 102 and the cap flange 104. A reaction tube (not shown) made of quartz capable of transmitting the electromagnetic wave may be provided in the case 102. When the reaction tube is provided in the case 102, the process vessel (that is, the case 102) may be configured such that the process chamber 201 is constituted by an inner space of the reaction tube. In addition, the process furnace may not include the cap flange 104. When the cap flange 104 is not included in the process furnace, the process chamber 201 may be defined by the case 102 with a closed ceiling.

A placement table (which is a mounting table) 210 is provided in the process chamber 201. The boat 217 serving as the substrate retainer configured to hold (support or accommodate) the wafer 200 serving as the substrate (or the wafers 200) is placed on an upper surface of the placement table 210. The wafer 200 (or the wafers 200) and quartz plates 101a and 101b serving as heat insulating plates are accommodated in the boat 217. The quartz plates 101a and 101b are placed with a predetermined interval therebetween to be vertically higher than and lower than the wafer 200, respectively, such that the wafer 200 (or the wafers 200) is interposed therebetween. Susceptors 103a and 103b may be provided between each of the quartz plates 101a and 101b and the wafer 200. That is, for example, one of the susceptors 103a and 103b may be provided between the quartz plate 101a and the wafer 200, and the other of the susceptors 103a and 103b may be provided between the wafer 200 and the quartz plate 101b. For example, a silicon plate (also referred to as a “Si plate”) or a silicon carbide plate (also referred to as a “SiC plate”) may be used as each of the susceptors 103a and 103b. The quartz plate 101a and the quartz plate 101b are identical to each other, and the susceptor 103a and the susceptor 103b are identical to each other. Therefore, in the present embodiments, the quartz plate 101a and the quartz plate 101b may be collectively or individually referred to as a quartz plate 101 unless they need to be distinguished separately. Similarly, the susceptor 103a and the susceptor 103b may be collectively or individually referred to as a susceptor 103 unless they need to be distinguished separately.

The case 102 serving as the process vessel is a flat and sealed vessel with a circular horizontal cross-section. The transfer housing (also referred to as a “transfer vessel”) 202 is made of a metal material such as aluminum (Al) and stainless steel (SUS). A space surrounded by the case 102 may be referred to as a reaction region 201 or the process chamber 201 serving as a process space, and a space surrounded by the transfer housing 202 may be referred to as the transfer region 203 or the transfer chamber 203 serving as a transfer space. While the process chamber 201 and the transfer chamber 203 are adjacent to each other in the horizontal direction according to the present embodiments, the present embodiments are not limited thereto. For example, the process chamber 201 and the transfer region 203 may be adjacent to each other in a vertical direction.

As shown in FIGS. 1, 2 and 3, a substrate loading/unloading port 206 is provided at a side surface of the transfer housing 202 adjacent to the gate valve 205. The wafer 200 is moved (transferred) between the process chamber 201 and the transfer chamber 203 through the substrate loading/unloading port 206.

An electromagnetic wave supplier (which is an electromagnetic wave supply structure) serving as a heater described later in detail is provided at a side surface of the case 102. The electromagnetic wave such as a microwave supplied through the electromagnetic wave supplier is introduced (supplied) into the process chamber 201 to heat the components such as the wafer 200 and to process the wafer 200.

The placement table 210 is supported by a shaft 255 serving as a rotating shaft. The shaft 255 penetrates a bottom of the case 102 and is connected to a driver 267 at an outside of transfer vessel 202. The driver 267 is configured to rotate the shaft 255. The wafer 200 accommodated in the boat 217 may be rotated by rotating the shaft 255 and the placement table 210 by operating the driver 267. A bellows 212 covers a lower end portion of the shaft 255 to maintain an inside of the process chamber 201 and an inside of the transfer region 203 airtight.

According to the present embodiments, the driver 267 is configured to elevate and lower the shaft 255. By operating the driver 267 based on a height of the substrate loading/unloading port 206, the placement table 210 may be elevated or lowered until the wafer 200 reaches a wafer transfer position when the wafer 200 is transferred, and the placement table 210 may be elevated or lowered until the wafer 200 reaches a processing position in the process chamber 201 (hereinafter, also referred to as a “wafer processing position”) when the wafer 200 is processed.

An exhauster (which is an exhaust structure) configured to exhaust an inner atmosphere of the process chamber 201 is provided below the process chamber 201 on an outer circumference of the placement table 210. As shown in FIG. 3, an exhaust port 221 is provided in the exhauster. An exhaust pipe 231 is connected to the exhaust port 221. A pressure regulator 244 such as an APC (Automatic Pressure Controller) valve and a vacuum pump 246 are sequentially connected to the exhaust pipe 231 in series.

According to the present embodiments, for example, the APC valve capable of adjusting an opening degree thereof in accordance with the inner pressure of the process chamber 201 may be used as the pressure regulator 244. In the present specification, the pressure regulator 244 may also be referred to as the APC valve 244. However, in the embodiments, the pressure regulator 244 is not limited to the APC valve. The pressure regulator 244 may be embodied by a combination of a conventional opening/closing valve and a pressure regulating valve so long as it is possible to receive information on the inner pressure of the process chamber 201 (that is, a feedback signal from a pressure sensor 245 which will be described later) and to adjust an exhaust amount based on the received information.

The exhauster (also referred to as an “exhaust system” or an “exhaust line”) is constituted mainly by the exhaust port 221, the exhaust pipe 231 and the pressure regulator 244. It is also possible to configure the exhaust port 221 to surround the placement table 210 such that a gas can be exhausted from the entire circumference of the wafer 200 through the exhaust port 221 surrounding the placement table 210. The exhauster may further include the vacuum pump 246.

The cap flange 104 is provided with a gas supply pipe 232 through which a process gas such as an inert gas, a source gas and a reactive gas used for performing various substrate processing is supplied into the process chamber 201.

A mass flow controller (MFC) 241 serving as a flow rate controller (flow rate control structure) and a valve 243 serving as an opening/closing valve are sequentially installed at the gas supply pipe 232 in order from an upstream side to a downstream side of the gas supply pipe 232. For example, a nitrogen (N₂) gas supply source (not shown) serving as a source of the inert gas is connected to the upstream side of the gas supply pipe 232, and the N₂ gas serving as the inert gas is supplied into the process chamber 201 via the MFC 241 and the valve 243. When two or more kinds of gases are used for the substrate processing, it is possible to supply the gases into the process chamber 201 by connecting one or more gas supply pipes to the gas supply pipe 232 at a downstream side of the valve 243 provided at the supply pipe 232. An MFC serving as a flow rate controller and a valve serving as an opening/closing valve may be sequentially installed at each of the one or more gas supply pipes in order from an upstream side to a downstream side of each of the one or more gas supply pipes. In addition, different gas supply pipes, each provided with an MFC and a valve may be provided for each type of the gases.

A gas supplier (which is a gas supply system or a gas supply structure) is constituted mainly by the gas supply pipe 232, the MFC 241 and the valve 243. When the inert gas is supplied through the gas supply pipe 232, the gas supplier may also be referred to as an inert gas supplier (which is an inert gas supply system or an inert gas supply structure). For example, a rare gas such as argon (Ar) gas, helium (He) gas, neon (Ne) gas and xenon (Xe) gas may be used as the inert gas instead of the N₂ gas.

A temperature sensor 263 serving as a non-contact type temperature detector is provided at the cap flange 104. By adjusting an output of a microwave oscillator 655 which will be described later based on temperature information detected by the temperature sensor 263, the wafer 200 serving as the substrate is heated such that a desired temperature distribution of a temperature of the wafer 200 can be obtained. For example, the temperature sensor 263 is constituted by a radiation thermometer such as an IR (Infrared Radiation) sensor. The temperature sensor 263 is provided so as to measure a surface temperature of the quartz plate 101a or a surface temperature of the wafer 200. When the susceptor 103 described above is provided, the temperature sensor 263 may measure a surface temperature of the susceptor 103.

In the present specification, the term “temperature of the wafer 200” (or wafer temperature) may refer to a wafer temperature converted by temperature conversion data described later (that is, an estimated wafer temperature), may refer to a temperature obtained directly by measuring the temperature of the wafer 200 by the temperature sensor 263, or may refer to both of them.

By acquiring transition data of a temperature change of the quartz plate 101 (or the susceptor 103) and the wafer 200 in advance, the temperature conversion data indicating a correlation between a temperature of the quartz plate 101 (or the susceptor 103) and the temperature of the wafer 200 may be stored in a memory 121c or may be stored in an external memory 123, which will be described later. By preparing the temperature conversion data in advance as described above, it is possible to estimate the temperature of the wafer 200 by measuring the temperature of the quartz plate 101 (or the susceptor 103) alone and it is also possible to control the output of the microwave oscillator 655 (that is, to control the heater) based on the estimated temperature of the wafer 200.

While the radiation thermometer is exemplified as the temperature sensor 263 of measuring the temperature of the wafer 200 serving as the substrate according to the present embodiments, the present embodiments are not limited thereto. A thermocouple may be used as the temperature sensor 263 to measure the temperature of the wafer 200, or both the thermocouple and the non-contact type temperature detector (non-contact type thermometer) may be used as the temperature sensor 263 to measure the temperature of the wafer 200. However, when the thermocouple is used as the temperature sensor 263 to measure the temperature of the wafer 200, it is preferable to provide (dispose) the thermocouple in the vicinity of the wafer 200 to measure the temperature the wafer 200. That is, since it is preferable to dispose the thermocouple in the process chamber 201, the thermocouple itself may be heated by the microwave supplied from the microwave oscillator 655 described later. As a result, it is impossible to accurately measure the temperature of the wafer 200 using the thermocouple. Therefore, it is preferable to use the non-contact type thermometer as the temperature sensor 263.

While the temperature sensor 263 is provided at the cap flange 104 according to the present embodiments, the present embodiments are not limited thereto. For example, the temperature sensor 263 may be provided at the placement table 210. While the temperature sensor 263 is directly disposed at the cap flange 104 or the placement table 210 according to the present embodiments, the present embodiments are not limited thereto. For example, the temperature sensor 263 may measure the temperature of the wafer 200 indirectly by measuring the radiation reflected by a component such as a mirror and emitted through a measurement window provided in the cap flange 104 or the placement table 210. While single temperature sensor 263 is shown in FIG. 3 according to the present embodiments, the present embodiments are not limited thereto. A plurality of temperature sensors may be provided according to the present embodiments.

Electromagnetic wave introduction ports 653-1 and 653-2 are provided at the side wall of the case 102. One end of a waveguide 654-1 and one end of a waveguide 654-2 through which the electromagnetic wave is supplied into the process chamber 201 are connected to the electromagnetic wave introduction ports 653-1 and 653-2, respectively. The other end of the waveguide 654-1 and the other end of the waveguide 654-2 are connected to microwave oscillators (hereinafter, also referred to as electromagnetic wave sources) 655-1 and 655-2, respectively, serving as heating sources configured to supply the electromagnetic wave into the process chamber 201 to heat the process chamber 201. The microwave oscillators 655-1 and 655-2 are configured to supply the electromagnetic wave such as the microwave to the waveguides 654-1 and 654-2, respectively. For example, a magnetron or a klystron may be used as the microwave oscillators 655-1 and 655-2. In the present specification, unless they need to be distinguished separately, the electromagnetic wave introduction ports 653-1 and 653-2 may be collectively or individually referred to as an electromagnetic wave introduction port 653, the waveguides 654-1 and 654-2 may be collectively or individually referred to as a waveguide 654, and the microwave oscillators 655-1 and 655-2 may be collectively or individually referred to as the microwave oscillator 655.

Preferably, a frequency of the electromagnetic wave generated by the microwave oscillator 655 is controlled such that the frequency is within a range from 13.56 MHz to 24.125 GHz. More preferably, the frequency is controlled to a frequency of 2.45 GHz or 5.8 GHz. In the present embodiments, the frequency of each of the microwave oscillators 655-1 and 655-2 may be the same or may be different.

While the two microwave oscillators 655-1 and 655-2 are provided on the same side surface of the case 102 according to the present embodiments, the present embodiments are not limited thereto. For example, the microwave oscillator 655 including at least one microwave oscillator may be provided according to the present embodiments. In addition, the microwave oscillator 655-1 may be provided on one side surface of the case 102 and the microwave oscillator 655-2 may be provided on another side surface of the case 102 such as a side surface facing the side surface of the case 102 at which the microwave oscillator 655-1 is provided. An electromagnetic wave supplier (which is an electromagnetic wave supply structure or an electromagnetic wave supply apparatus) serving as the heater is constituted mainly by the microwave oscillators 655-1 and 655-2, the waveguides 654-1 and 654-2 and the electromagnetic wave introduction ports 653-1 and 653-2. The electromagnetic wave supplier may also be referred to as a microwave supplier (which is a microwave supply structure or a microwave supply apparatus).

A controller 121 which will be described later is connected to each of the microwave oscillators 655-1 and 655-2. The temperature sensor 263 configured to measure the temperature of the wafer 200 or the temperature of the quartz plate 101a (or the quartz plate 101b) is connected to the controller 121. The temperature sensor 263 may be configured to measure the temperature of the quartz plate 101 (or the susceptor 103) or the wafer 200 as described above and to transmit the measured temperature to the controller 121. The controller 121 is configured to control the heating of the wafer 200 by controlling the outputs of the microwave oscillators 655-1 and 655-2.

According to the present embodiments, for example, the microwave oscillators 655-1 and 655-2 are controlled by the same control signal transmitted from the controller 121. However, the present embodiments are not limited thereto. For example, the microwave oscillator 655-1 and the microwave oscillator 655-2 may be individually controlled by individual control signals transmitted from the controller 121 to the microwave oscillator 655-1 and the microwave oscillator 655-2, respectively.

### Controller

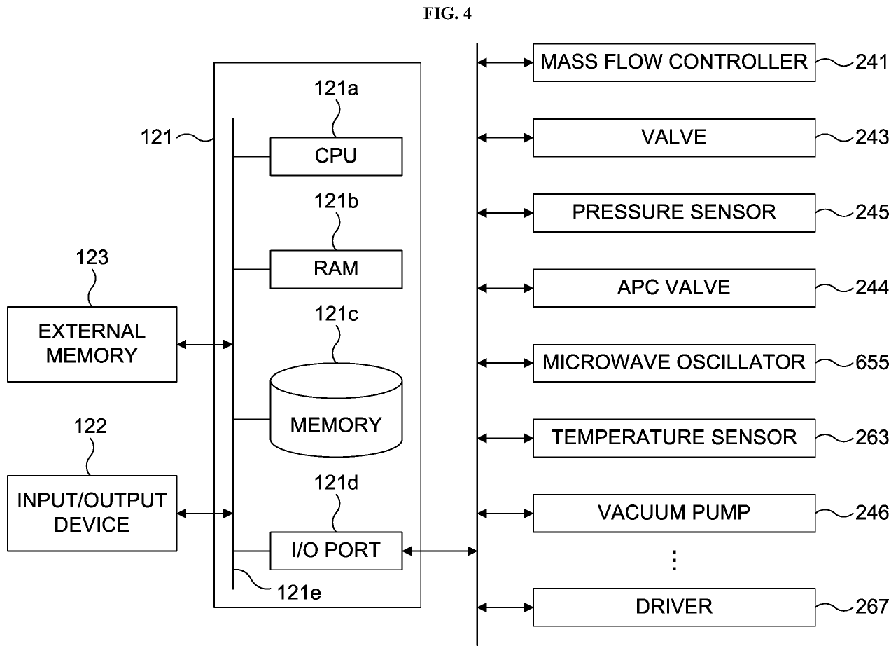

As shown in FIG. 4, the controller 121 serving as a control structure (or a control apparatus) may be constituted by a computer including a CPU (Central Processing Unit) 121a, a RAM (Random Access Memory) 121b, the memory 121c and an I/O port 121d. The RAM 121b, the memory 121c and the I/O port 121d may exchange data with the CPU 121a through an internal bus 121e. For example, an input/output device 122 such as a touch panel is connected to the controller 121.

For example, the memory device 121c is configured by a component such as a flash memory and an HDD (Hard Disk Drive). For example, a control program configured to control the operation of the substrate processing apparatus 100 and a process recipe containing information on the sequences and conditions of the annealing process (modification process) of a substrate processing described later may be readably stored in the memory device 121c. The process recipe is obtained by combining steps of the substrate processing described later such that the controller 121 can execute the steps to acquire a predetermined result, and functions as a program. Hereinafter, the process recipe and the control program are collectively or individually referred to as a “program”. The process recipe may be simply referred to as a “recipe”. In the present specification, the term “program” may refer to the recipe alone, may refer to the control program alone, or may refer to both of the recipe and the control program. The RAM 121b functions as a memory area (work area) where a program or data read by the CPU 121a is temporarily stored.

The I/O port 121d is connected to the above-described components such as the mass flow controller (MFC) 241, the valve 243, the pressure sensor 245, the APC valve 244, the vacuum pump 246, the temperature sensor 263, the driver 267 and the microwave oscillator 655.

The CPU 121a is configured to read the control program from the memory 121c and execute the read control program. Furthermore, the CPU 121a is configured to read the recipe from the memory 121c according to an operation command inputted from the input/output device 122. According to the contents of the read recipe, the CPU 121a may be configured to control various operations such as a flow rate adjusting operation for various gases by the MFC 241, an opening and closing operation of the valve 243, a pressure adjusting operation by the APC valve 244 based on the pressure sensor 245, a start and stop of the vacuum pump 246, an output adjusting operation by the microwave oscillator 655 based on the temperature sensor 263, an operation of adjusting rotation and rotation speed of the placement table 210 (or an operation of adjusting rotation and rotation speed of the boat 217) by the driver 267 and an elevating and lowering operation of the placement table 210 (or an elevating and lowering operation of the boat 217) by the driver 267.

The controller 121 may be embodied by installing the above-described program stored in the external memory 123 into a computer. For example, the external memory 123 may include a magnetic disk such as a hard disk, an optical disk such as a CD, a magneto-optical disk such as an MO and a semiconductor memory such as a USB memory and an SSD. The memory 121c or the external memory 123 may be embodied by a non-transitory computer readable recording medium. Hereafter, the memory 121c and the external memory 123 are collectively or individually referred to as a “recording medium”. In the present specification, the term “recording medium” may refer to the memory 121c alone, may refer to the external memory 123 alone, and may refer to both of the memory 121c and the external memory 123. Instead of the external memory 123, a communication means such as the Internet and a dedicated line may be used for providing the program to the computer.

### (2) Substrate Processing

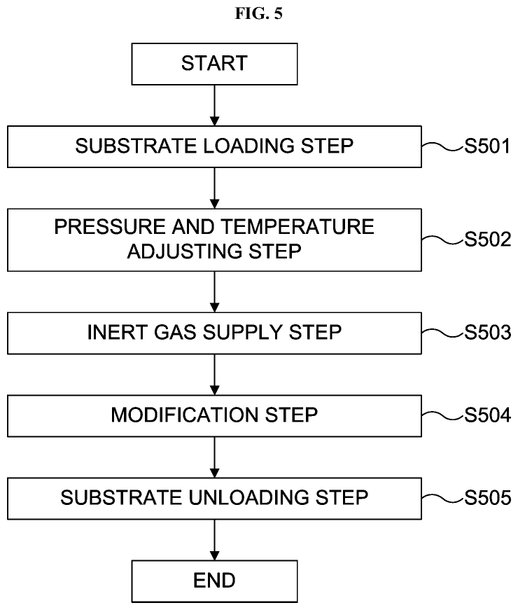

Hereinafter, an exemplary sequence of the substrate processing of modifying (crystallizing) a film formed on the wafer 200 serving as the substrate, which is a part of manufacturing processes of a semiconductor device, will be described with reference to a flow chart shown in FIG. 5. For example, the film such as an amorphous silicon film serving as a silicon-containing film is processed according to the substrate processing. The exemplary sequence of the substrate processing is performed by using the process furnace of the substrate processing apparatus 100 described above. Hereinafter, the components constituting the substrate processing apparatus 100 are controlled by the controller 121. According to the present embodiments, processing contents of the substrate processing performed by the plurality of process furnaces provided in the substrate processing apparatus 100 are the same. That is, the same recipe is used in the plurality of process furnaces to perform the substrate processing. Similar to the configurations of the plurality of process furnaces described above, the substrate processing performed by one process furnace alone will be described and the detailed descriptions of the substrate processing performed by the other process furnaces will be omitted.

In the present specification, the term “wafer” may refer to “a wafer itself” or may refer to “a wafer and a stacked structure (aggregated structure) of a predetermined layer (or layers) or a film (or films) formed on a surface of a wafer”. In the present specification, the term “a surface of a wafer” may refer to “a surface of a wafer itself” or may refer to “a surface of a predetermined layer or a film formed on a wafer”. Thus, in the present specification, “forming a predetermined layer (or film) on a wafer” may refer to “forming a predetermined layer (or film) on a surface of a wafer itself” or may refer to “forming a predetermined layer (or film) on a surface of another layer or another film formed on a wafer”. In the present specification, the terms “substrate” and “wafer” may be used as substantially the same meaning. That is, the term “substrate” may be substituted by “wafer” and vice versa.

### Substrate Loading Step S501

As shown in FIGS. 1 and 3, the wafer 200 placed on one of the tweezers 125a-1 and 125a-2 (or two wafers 200 placed on both of the tweezers 125a-1 and 125a-2) is (or are) transferred (loaded) into the predetermined process chamber 201 while the gate valve 205 is opened by an opening and closing operation of the gate valve 205 (S501).

### Pressure and Temperature Adjusting Step S502

After the wafer 200 is loaded into the process chamber 201, the inner atmosphere of the process chamber 201 is controlled (adjusted) such that the inner pressure of the process chamber 201 reaches and is maintained to a predetermined pressure (for example, a pressure ranging from 10 Pa to 102,000 Pa). Specifically, the opening degree of the APC valve (that is, the pressure regulator) 244 is feedback-controlled based on pressure information detected by the pressure sensor 245 to adjust the inner pressure of the process chamber 201 to the predetermined pressure while vacuum-exhausting the process chamber 201 by the vacuum pump 246. In addition, in parallel with controlling the inner pressure of the process chamber 201, the electromagnetic wave supplier may be controlled so as to heat the process chamber 201 to a predetermined temperature as a preliminary heating (S502). When an inner temperature of the process chamber 201 is elevated to a predetermined substrate processing temperature by the electromagnetic wave supplier, it is preferable to elevate the inner temperature of the process chamber 201 while the output of the electromagnetic wave supplier is controlled to be less than that of the electromagnetic wave supplier when the modification process described later is performed. In this manner, it is possible to prevent the wafer 200 from being deformed or damaged. In addition, when the substrate processing is performed under the atmospheric pressure, an inert gas supply step S503 described later may be performed after adjusting the inner temperature of the process chamber 201 alone without adjusting the inner pressure of the process chamber 201.

### Inert Gas Supply Step S503

After the inner pressure and the inner temperature of the process chamber 201 are controlled to predetermined values by the pressure and temperature adjusting step S502, the driver 267 rotates the shaft 255 and rotates the wafer 200 via the boat 217 on the placement table 210. While the driver 267 rotates the wafer 200, the inert gas such as the nitrogen gas is supplied into the process chamber 201 through the gas supply pipe 232 (S503). In the inert gas supply step S503, the inner pressure of the process chamber 201 is adjusted to a predetermined pressure. For example, the predetermined pressure of the inert gas supply step S503 may range from 10 Pa to 102,000 Pa, more preferably, from 101,300 Pa to 101,650 Pa. Alternatively, the driver 267 may rotate the shaft 255 in the substrate loading step S501, that is, after the wafer 200 is loaded into the process chamber 201.

### Modification Step S504

While maintaining the inner pressure of the process chamber 201 at a predetermined pressure, the microwave oscillator 655 supplies the microwave into the process chamber 201 through the above-described components such as the electromagnetic wave introduction port 653 and the waveguide 654. By supplying the microwave into the process chamber 201, the wafer 200 is heated to a predetermined temperature. For example, the predetermined temperature of the modification step S504 may be within a temperature range from 100° C. to 1,000° C., preferably from 400° C. to 900° C., and more preferably from 500° C. to 700° C. By performing the substrate processing at the temperature described above, it is possible to perform the modification step S504 of the substrate processing at the temperature at which the wafer 200 efficiently absorbs the microwave. Therefore, it is possible to improve the speed of the modification process in the modification step S504. That is, when the wafer 200 is processed at a temperature lower than 100° C. or higher than 1,000° C., a surface of the wafer 200 may be deformed, so that the microwave is hardly absorbed on the surface of the wafer 200. This may cause difficulties in heating the wafer 200. Therefore, it is preferable to perform the modification step S504 of the substrate processing at the temperature range described above.

By controlling the microwave oscillator 655 as described above, the wafer 200 is heated so that the amorphous silicon film formed on the surface of the wafer 200 is modified (crystallized) into a polysilicon film (S504). That is, it is possible to modify the wafer 200 uniformly. In addition, when the measured temperature of the wafer 200 exceeds or falls below the temperature range described above, it is also possible to control the temperature of the wafer 200 to be within the temperature range by decreasing (or increasing) the output of the microwave oscillator 655 instead of turning off (or on) the microwave oscillator 655 by the ON/OFF control. When the temperature of the wafer 200 returns to a temperature within the temperature range after decreasing (or increasing) the output of the microwave oscillator 655, the output of the microwave oscillator 655 may be increased (or decreased).

After a predetermined processing time has elapsed, the rotation of the boat 217, the supply of the gas, the supply of the microwave and the exhaust via the exhaust pipe 231 are stopped.

### Substrate Unloading Step S505

After returning the inner pressure of the process chamber 201 to the atmospheric pressure, the gate valve 205 is opened for the process chamber 201 to communicate with the transfer chamber 203. Thereafter, the wafer 200 placed on the boat 217 is transferred to the transfer chamber 203 by the tweezers 125a of the transfer device 125 (S505).

By performing (or repeatedly performing) the above-described steps, the wafer 200 is modified. Then, a next substrate processing may be performed.

### (3) Shape of Quartz Plate and Quartz Plate Retaining Structure of Boat

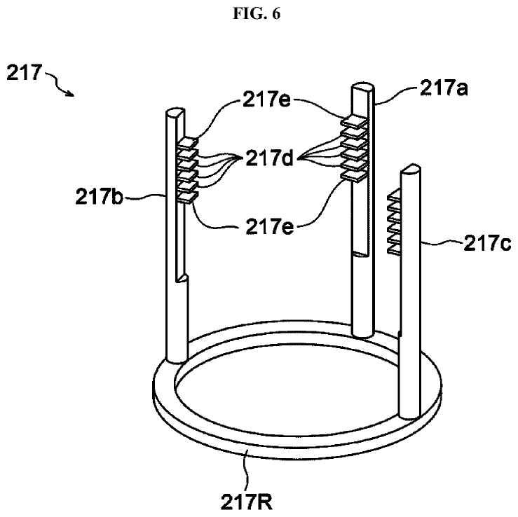

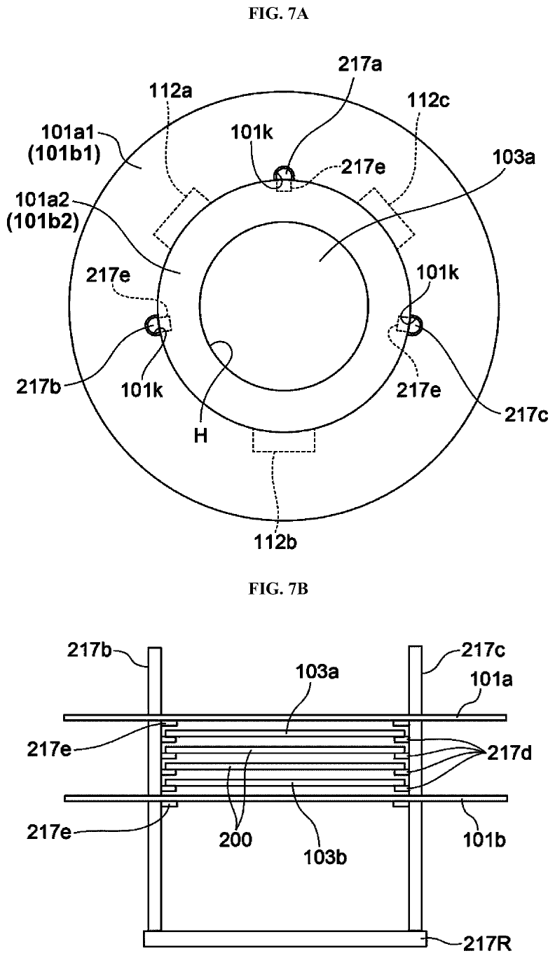

Hereinafter, with reference to FIGS. 6, 7A and 7B, a shape of the quartz plate 101 and an example of a retaining structure of the boat 217 where the quartz plate 101 is supported will be described. In FIGS. 6, 7A and 7B, a ceiling plate (end plate) of the boat 217 described above is omitted for simplification.

As shown in FIG. 6, the boat 217 includes a bottom ring 217R and boat columns (which are support columns) 217a through 217c. The bottom ring 217R is of an annular shape, and the boat columns 217a through 217c extend vertically with a predetermined interval between each other on a circumference of the bottom ring 217R. On each of the boat columns 217a through 217c, a plurality of wafer supports 217d, which are configured to support the wafer 200 and the susceptor 103, are provided on an inner side of each of the boat columns 217a through 217c to face centers of the wafer 200 and the susceptor 103 (that is, the plurality of wafer supports 217d extend toward a central axis of the boat 217) along a longitudinal direction (vertical direction) of the boat columns 217a through 217c. For example, four wafer supports 217d are provided on each of the boat columns 217a through 217c. Hereinafter, the plurality of wafer supports 217d may be collectively or individually referred to as wafer supports 217d. For example, two quartz plate supports (that is, an upper quartz plate support and a lower quartz plate support) 217e configured to support the quartz plate 101 are provided on the same inner side of each of the boat columns 217a through 217c on which the wafer supports 217d are provided. The upper quartz plate support of the quartz plate supports 217e is provided above the four wafer supports 217d and the lower quartz plate support of the quartz plate supports 217e is provided below the four wafer supports 217d such that the four wafer supports 217d are arranged in the vertical direction between the upper and the lower of the quartz plate supports 217e. As shown in FIG. 7B, the upper quartz plate support of the quartz plate supports 217e is disposed above an uppermost wafer support among the wafer supports 217d in the vertical direction with an interval therebetween. Similarly, the lower quartz plate support of the quartz plate supports 217e is disposed below a lowermost wafer support among the wafer supports 217d in the vertical direction with an interval therebetween. For example, an interval between two wafer supports adjacent to each other among the wafer supports 217d in the vertical direction and the interval between the upper quartz plate support and the uppermost wafer support or between the lower quartz plate support and the lowermost wafer support may be set to be within a range from 5 mm to 15 mm.

The two wafers 200 of a disk shape are supported by the wafer supports 217d adjacent to each other in the vertical direction, and are arranged at the inner side of the boat columns 217a through 217c such that surfaces of each wafer 200 face upward and downward. For example, the susceptors 103a and 103b are supported by the wafer supports 217d such that the two wafers 200 of a click shape are provided between the susceptors 103a and 103b in the vertical direction. The susceptors 103a and 103b are arranged at the inner side of the boat columns 217a through 217c such that surfaces of each of the susceptors 103a and 103b face upward and downward. For example, the susceptor 103 may be configured as a silicon plate, and configured to heat the wafer 200 indirectly by absorbing the microwave and generating the heat by itself.

As shown in FIG. 7A, the quartz plate 101a is of an annular shape (ring shape), and may include a first ring plate 101a1 and a second ring plate 101a2 serving as a heat retainer (which is a heat insulator). The first ring plate 101a1 and the second ring plate 101a2 are also of an annular shape (ring shape) with an empty central portion (that is, a through port, also referred to as a “through-hole”), H is provided at the central portion). An inner diameter of the first ring plate 101a1 is greater than or substantially the same as an outer diameter of the second ring plate 101a2, and the second ring plate 101a2 is provided in an inner side of the first ring plate 101a1 to be aligned in a manner concentric with the first ring plate 101a1. A shape of the quartz plate 101b is the same as that of the quartz plate 101a. Similar to the quartz plate 101a, the quartz plate 101b may include a first ring plate 101b1 and a second ring plate 101b2 serving as a heat retainer (which is a heat insulator). The second ring plate 101a2 is supported by the upper quartz plate support of the quartz plate supports 217e, and is arranged above the wafer 200 and the susceptor 103. The second ring plate 101b2 is supported by the lower quartz plate support of the quartz plate supports 217e, and is arranged below the wafer 200 and the susceptor 103.

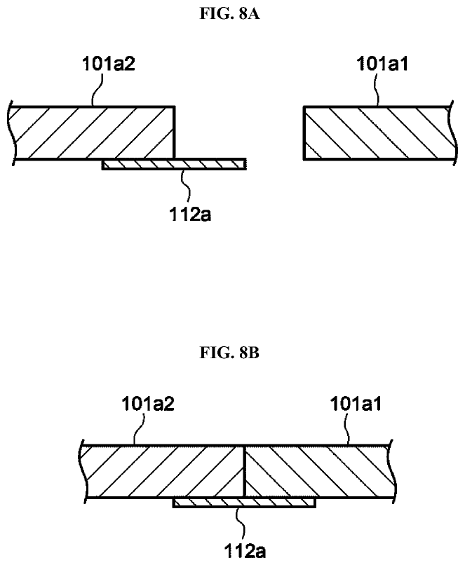

As shown in FIG. 7A, supports 112a, 112b and 112c, which serve as a retaining structure, protrude radially outward from an outer circumference of each of the second ring plates 101a2 and 101b2. As shown in FIGS. 8A and 8B, an upper surface of the support 112a is arranged on substantially the same surface as a lower surface of the second ring plate 101a2. The same also applies to upper surfaces of the supports 112b and 112c.

Outer diameters of the first ring plates 101a1 and 101b1 are greater than an outer diameter of the wafer 200. Notches 101k are provided on an inner circumference of each of the first ring plates 101a1 and 101b1 at positions corresponding to the boat columns 217a through 217c. The notches 101k are provided apart from one another in a circumferential direction of each of the first ring plates 101a1 and 101b1. By arranging the boat columns 217a through 217c through inner sides of the notches 101k, it is possible to dispose the inner circumference of each of the first ring plates 101a1 and 101b1 closer to the outer circumference of each of the second ring plates 101a2 and 101b2. The first ring plates 101a1 and 101b1 are supported by the supports 112a, 112b and 112c from thereunder, respectively.

As the quartz plate 101, it is preferable to use a quartz plate whose reflectance with respect to a heat ray (light) is high. For example, a quartz plate such as an opaque quartz plate, a transparent quartz plate with a roughened surface and a quartz plated in which bubbles are inserted to increase the reflectance with respect to the heat ray (light) may be used as the quartz plate 101. Assuming that the reflectance with respect to the heat ray (light) of ordinary quartz is about 5%, it is preferable to use the quartz plate whose reflectance with respect to the heat ray (light) is about 50%. The quartz itself is not directly heated because it transmits the microwave. However, by increasing the reflectance with respect to the heat ray (light), the heat such as a visible light from the wafer 200 and the susceptor 103 can be reflected by the quartz plate 101. Thereby, it is possible to improve a function of maintaining the temperatures of the wafer 200 and the susceptor 103.

By providing the quartz plate 101 and the boat 217 as described above and by arranging the wafer 200, the susceptor 103 and the quartz plate 101 as shown in FIGS. 7A and 7B, the wafer 200, the susceptor 103 and the quartz plate 101 are arranged at positions where they are not in contact with one another (also referred to as “non-contacting positions”). In addition, an outer circumferential portion of the quartz plate 101 is located radially outside an outer circumferential portion (also referred to as an “end portion”, an “edge portion” or a “peripheral portion”) of the wafer 200. Further, a central portion of the wafer 200 is arranged in an exposed state without being covered by the quartz plate 101. As a result, by maintaining a temperature of the outer circumferential portion of the wafer 200 and releasing (dissipating) the heat through the central portion of the wafer 200, it is possible to improve a uniformity of a heat distribution of the wafer 200, and it is also possible to improve a uniformity of the modification of the wafer 200.

While the present embodiments are described by way of an example in which the quartz plate of a ring shape with a circular outer circumference is used as the quartz plate 101, the outer circumference of the quartz plate 101 is not limited thereto. For example, the outer circumference of the quartz plate 101 may be polygonal or of any other shape.

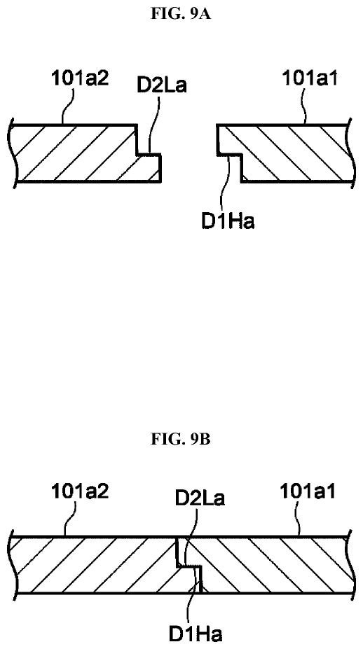

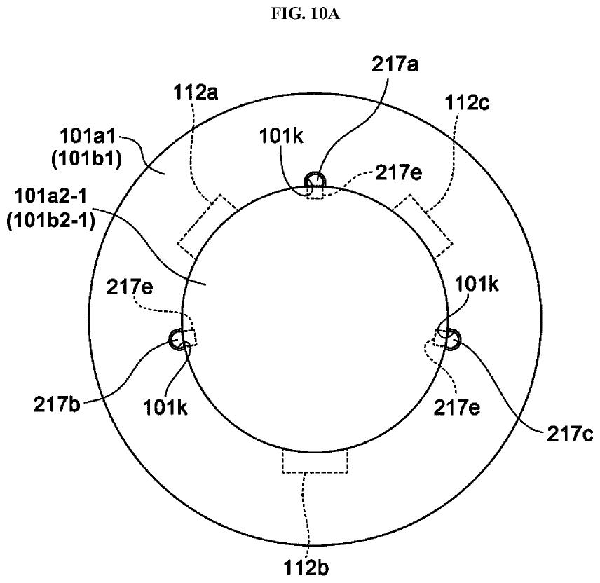

While the present embodiments are described by way of an example in which the supports 112a, 112b and 112c are provided on the second ring plates 101a2 and 101b2 to support the first ring plates 101a1 and 101b1, other retaining structure may be used instead of the supports 112a, 112b and 112c. For example, as shown in FIG. 9A, a stepped portion D2La is provided by cutting out an upper portion of the outer circumference of the second ring plate 101a2, and a stepped portion D1Ha is provided by cutting out a lower portion of the inner circumference of the first ring plate 101a1. The stepped portions D1Ha and D2La are provided over the entire region in the circumferential direction. As shown in FIG. 9B, by engaging the stepped portion D2La and the stepped portion D1Ha with each other such that the stepped portion D1Ha is supported by the stepped portion D2La, it is possible to support the first ring plate 101a1 by the stepped portion D1Ha and the stepped portion D2La. The same can also apply to the first ring plate 101b1 and the second ring plate 101b2.

By supporting the first ring plates 101a1 and 101b1 using the stepped portions D1Ha and D2La as described above, it is possible to increase the strength of the quartz plates 101a and 101b. In addition, it is possible to flatten surfaces of the quartz plates 101a and 101b since the supports 112a, 112b and 112c can be omitted.

### (4) Effects according to Present Embodiments

According to the present embodiments described above, it is possible to provide one or more of the following effects.

(a) By suppressing the heat escape through the outer circumferential portion of the wafer 200 by the quartz plate 101 and promoting the heat release (heat dissipation) through the vicinity of the center of the wafer 200 by the quartz plate 101, it is possible to uniformly process the wafer 200.

(b) By adopting the quartz plate 101 whose reflectance is high, it is possible to further improve a uniformity of the heat distribution on the wafer 200. As a result, it is possible to uniformly process the wafer 200.

(c) By adopting the quartz plate 101 of a ring shape, it is possible to uniformly heat the wafer 200. As a result, it is possible to improve a processing uniformity on the surface of the wafer 200.

For example, the substrate processing apparatus 100 according to the embodiments described above is not limited to the example described above. That is, the embodiments described above may be modified as shown in the following modified examples.

### FIRST MODIFIED EXAMPLE

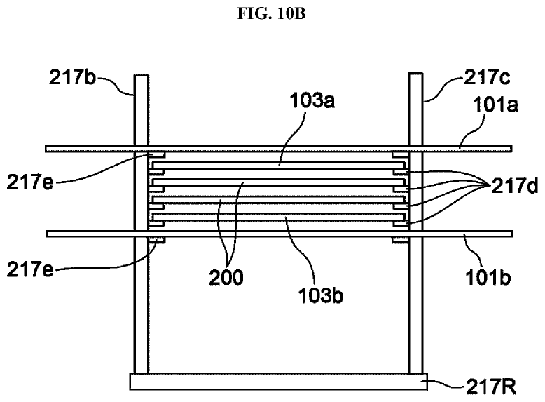

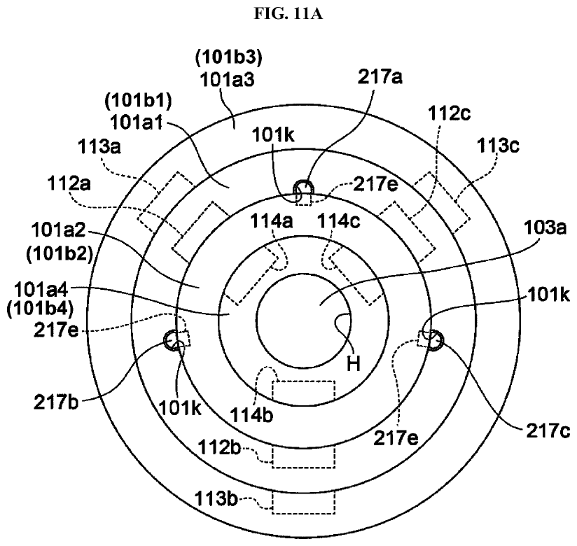

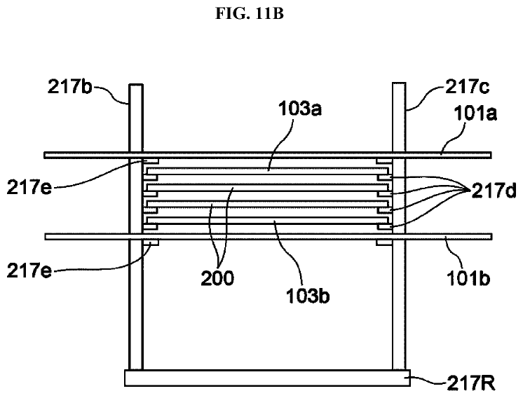

Hereinafter, a first modified example of the present embodiment will be described. As shown in FIGS. 10A and 10B, according to the first modified example, a second plate 101a2-1 on which no hole is provided in a central portion thereof is used instead of the second ring plate 101a2. A second plate 101b2-1 similar to the second plate 101a2-1 is used instead of the second ring plate 101b2.

According to the first modified example, similar to the above-described embodiments, an outer diameter of the quartz plate 101 is greater than the outer diameter of the wafer 200. That is, the outer circumferential portion of the quartz plate 101 is located radially outside the outer circumferential portion (also referred to as the “end portion”, the “edge portion” or the “peripheral portion”) of the wafer 200. The quartz plate 101 according to the first modified example is of a disk shape, and no hole (cavity) is provided in an inner portion of the quartz plate 101 according to the first modified example. With such a configuration, it is possible to maintain (retain) a temperature of the outer circumferential portion of the wafer 200 while suppressing the heat escape from the central portion of the wafer 200. In FIGS. 10A and 10B, the ceiling plate (end plate) of the boat 217 described above is omitted for simplification.

### SECOND MODIFIED EXAMPLE

Hereinafter, a second modified example of the present embodiment will be described. As shown in FIGS. 11A and 11B, according to the second modified example, the quartz plate 101a further includes a third ring plate 101a3 and a fourth ring plate 101a4 in addition to the first ring plate 101a1 and the second ring plate 101a2.

An inner diameter of the third ring plate 101a3 is greater than or substantially the same as the outer diameter of the first ring plate 101a1, and an outer diameter of the third ring plate 101a3 is greater than the outer diameter of the first ring plate 101a. An outer diameter of the fourth ring plate 101a4 is less than or substantially the same as the inner diameter of the second ring plate 101a2, and an inner diameter of the fourth ring plate 101a4 is less than the inner diameter of the second ring plate 101a2. Similarly, the quartz plate 101b further includes a third ring plate 101b3 and a fourth ring plate 101b4 in addition to the first ring plate 101b1 and the second ring plate 101b2.

The retaining structures of the first ring plates 101a1 and 101b1 and the second ring plates 101a2 and 101b2 are the same as those in the embodiments described above.

The third ring plate 101a3 is arranged on an outer circumference of the first ring plate 101a1, and the fourth ring plate 101a4 is arranged on an inner circumference of the second ring plate 101a2. Further, the third ring plate 101b3 is arranged on an outer circumference of the first ring plate 101b1, and the fourth ring plate 101b4 is arranged on an inner circumference of the second ring plate 101b2.

The second ring plate 101a2 is provided with supports 114a, 114b and 114c protruding radially inward from the inner circumference of the second ring plate 101a2 with an interval therebetween in the circumferential direction. The fourth ring plate 101a4 is supported from thereunder by the supports 114a, 114b and 114c in the same manner as the first ring plate 101a1. Similarly, the second ring plate 101b2 is provided with supports 114a, 114b and 114c protruding radially inward from the inner circumference of the second ring plate 101b2 with an interval therebetween in the circumferential direction. The fourth ring plate 101b4 is supported from thereunder by the supports 114a, 114b and 114c in the same manner as the first ring plate 101b1.

The first ring plate 101a1 is provided with supports 113a, 113b and 113c protruding radially outward from the outer circumference of the first ring plate 101a1 with an interval therebetween in the circumferential direction. The third ring plate 101a3 is supported from thereunder by the supports 113a, 113b and 113c in the same manner as the first ring plate 101a1. Similarly, the first ring plate 101b1 is provided with the supports 113a, 113b and 113c protruding radially outward from the outer circumference of the first ring plate 101b1 with an interval therebetween in the circumferential direction. The third ring plate 101b3 is supported from thereunder by the supports 113a, 113b and 113c in the same manner as the first ring plate 101b1.

With such a configuration, it is possible to easily change an outer diameter and a hole diameter of the quartz plate 101 by attaching and detaching the third ring plates 101a3 and 101b3 and the fourth ring plates 101a4 and 101b4. Thereby, it is possible to easily adjust the uniformity as desired. In FIGS. 11A and 11B, the ceiling plate (end plate) of the boat 217 described above is omitted for simplification.

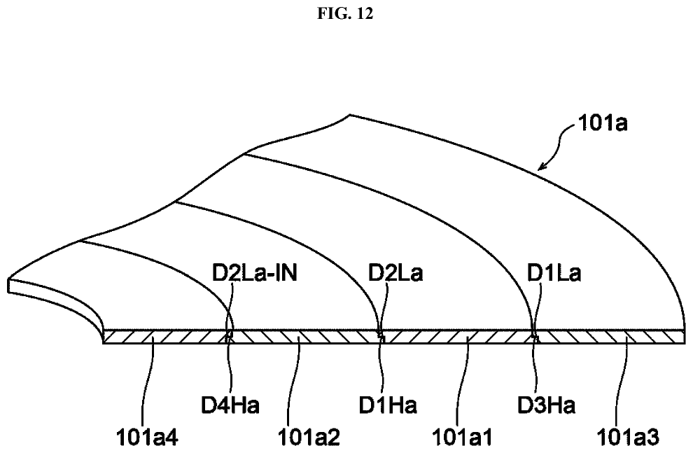

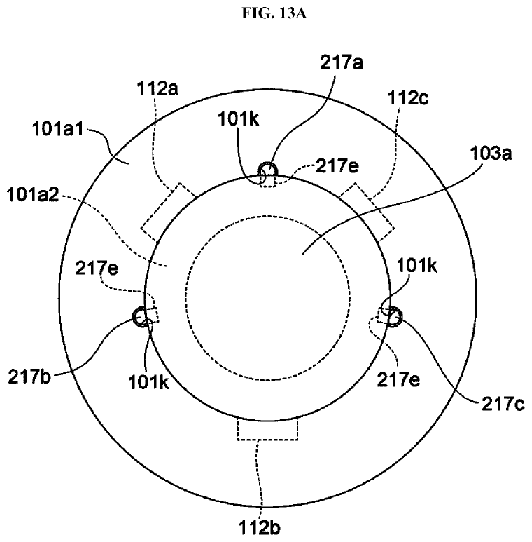

Further, according to the second modified example as shown in FIG. 12, instead of the supports 112a, 112b, 112c, 113a, 113b, 113c, 114a, 114b and 114c, stepped portions may be provided as the retaining structures. That is, there may be provided the stepped portion D2La obtained by cutting out the upper portion of the outer circumference of the second ring plate 101a2, the stepped portion D1Ha obtained by cutting out the lower portion of the inner circumference of the first ring plate 101a1, a stepped portion D2La-IN obtained by cutting out an upper portion of the inner circumference of the second ring plate 101a2, a stepped portion D4Ha obtained by cutting out a lower portion of an outer circumference of the fourth ring plate 101a4 and a stepped portion D3Ha obtained by cutting out a lower portion of the inner circumference of the third ring plate 101a3.

By engaging the stepped portion D2La and the stepped portion D1Ha with each other, it is possible to support the first ring plate 101a1 by the second ring plate 101a2. By engaging the stepped portion D2La-IN and the stepped portion D4Ha with each other, it is possible to support the fourth ring plate 101a4 by the second ring plate 101a2. By engaging a stepped portion D1La and the stepped portion D3Ha with each other, it is possible to support the third ring plate 101a3 by the first ring plate 101a1. Similarly, stepped portions may be provided at the quartz plate 101b as the retaining structures.

By using the stepped portions as the retaining structures as described above, it is possible to increase the strength of the quartz plates 101a and 101b. In addition, it is possible to flatten the surfaces of the quartz plates 101a and 101b since the supports 112a, 112b, 112c, 113a, 113b, 113c, 114a, 114b and 114c can be omitted.

### THIRD MODIFIED EXAMPLE

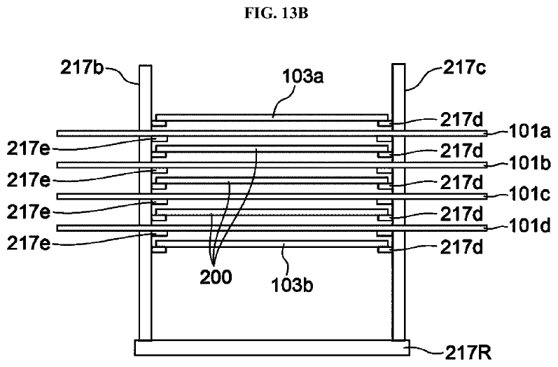

Hereinafter, a third modified example of the present embodiment will be described. As shown in FIG. 13B, according to the third modified example, the arrangement of the quartz plate 101, the susceptor 103 and the wafer 200 on the boat 217 is different from the embodiments described above. In addition, as the quartz plate 101, four quartz plates 101a, 101b, 101c and 101d are arranged in the boat 217.

Three wafers 200 are accommodated in the boat 217 by the wafer supports 217d with an interval therebetween. For example, the quartz plate 101b is arranged between an upper wafer and a middle wafer among the three wafers 200, and the quartz plate 101c is arranged between a lower wafer and the middle wafer among the three wafers 200. The quartz plate 101a is arranged above the upper wafer among the three wafers 200, and the quartz plate 101d is arranged below the lower wafer among the three wafers 200. Further, the susceptor 103a is arranged above the quartz plate 101a, and the susceptor 103b is arranged below the quartz plate 101d.

According to the third modified example, similar to the embodiments and the modified examples described above, the outer diameter of the quartz plate 101 is greater than the outer diameter of the wafer 200. That is, the outer circumferential portion of the quartz plate 101 is located radially outside the outer circumferential portion (also referred to as the “end portion”, the “edge portion” or the “peripheral portion”) of the wafer 200.

The quartz plate 101 is provided between the wafer 200 and the susceptor 103. With such a configuration, similar to the embodiments and the modified examples described above, it is possible to maintain the temperature of the outer circumferential portion of the wafer 200. In FIGS. 13A and 13B, the ceiling plate (end plate) of the boat 217 described above is omitted for simplification.

While the three wafers 200 are accommodated in the boat 217 according to the third modified example, the number of the wafers are not limited thereto. For example, four or more wafers 200 may be accommodated in the boat 217. Further, the quartz plate 101 may be arranged between the susceptor 103 and some of the wafers 200. Further, a distance (interval) between the wafers 200 may be different from a distance (interval) between the wafer 200 and the susceptor 103.

### Other Embodiments

While the technique is described by way of the embodiments and the modified examples described above, the above-described technique is not limited thereto. The above-described technique may be modified in various ways without departing from the gist thereof. For example, the present embodiments and the modified examples described above may be appropriately combined. It is possible to obtain the same advantageous effects when the present embodiments and the modified examples are appropriately combined.

For example, the present embodiments are described by way of an example in which the wafers 200 (for example, two wafers as shown in FIG. 3) are simultaneously batch-processed by placing the wafers 200 on the boat 217. However, the above-described technique is not limited thereto. For example, the above-described technique may also be applied to a case where only a single wafer 200 is placed on the boat 217 for the substrate processing, or the wafer 200 and a dummy wafer (not shown) are placed on the boat 217 for the substrate processing. By processing the substrate (that is, the wafer 200) using the dummy wafer, the heat capacity in the process chamber 201 can be approximated to the case where the two wafers 200 are placed on the boat 217 for the substrate processing. In addition, even when the single wafer 200 is placed on the boat 217 for the substrate processing, it is possible to obtain processing results similar to the case where the two wafers 200 are placed on the boat 217 for the substrate processing.

For example, the present embodiments are described by way of an example in which the amorphous silicon film serving as a film containing silicon as a main element is modified into the polysilicon film. However, the above-described technique is not limited thereto. The above-described technique may be applied to modify a film formed on the surface of the wafer 200 by supplying a gas containing at least one among oxygen (O), nitrogen (N), carbon (C) and hydrogen (H). When, for example, forming a hafnium oxide film (HfₓO_{y} film) serving as a high dielectric film on the wafer 200, the deficient oxygen in the hafnium oxide film can be supplemented and the characteristics of the high dielectric film can be improved by supplying the microwave to heat the wafer 200 while supplying a gas containing oxygen.

While the hafnium oxide film is mentioned above as an example, the above-described technique is not limited thereto. For example, the above-described technique may be applied to modify a metal-based oxide film, that is, an oxide film containing at least one metal element such as aluminum (Al), titanium (Ti), zirconium (Zr), tantalum (Ta), niobium (Nb), lantern (La), cerium (Ce), yttrium (Y), barium (Ba), strontium (Sr), calcium (Ca), lead (Pb), molybdenum (Mo) and tungsten (W). That is, the above-described substrate processing may be preferably applied to modify a film formed on the wafer 200 such as a TiOCN film, a TiOC film, a TiON film, a TiO film, a ZrOCN film, a ZrOC film, a ZrON film, a ZrO film, a HfOCN film, a HfOC film, a HfON film, a HfO film, a TaOCN film, a TaOC film, a TaON film, a TaO film, a NbOCN film, NbOC film, a NbON film, a NbO film, a AlOCN film, a AlOC film, a AlON film, a AlO film, a MoOCN film, a MoOC film, a MoON film, a MoO film, a WOCN film, a WOC film, a WON film and a WO film.

Without being limited to the high dielectric film, it is also possible to heat a film containing silicon as a main element and doped with impurities. A silicon-based film such as a silicon nitride film (SiN film), a silicon oxide film (SiO film), a silicon oxycarbide film (SiOC film), a silicon oxycarbonitride film (SiOCN film) and a silicon oxynitride film (SiON film) may be used as the above-mentioned film containing silicon as the main element. For example, the impurities may include at least one element among boron (B), carbon (C), nitrogen (N), aluminum (Al), phosphorus (P), gallium (Ga) and arsenic (As).

In addition, the above-described technique may be applied to modify a photoresist film based on at least one photoresist among methyl methacrylate resin (polymethyl methacrylate, PMMA), epoxy resin, novolac resin and polyvinyl phenyl resin.

While the present embodiments are described by way of an example in which the substrate processing is performed as a part of the manufacturing processes of the semiconductor device, the above-described technique is not limited thereto. For example, the above-described technique may be applied to other substrate processing such as a patterning process of a manufacturing process of a liquid crystal panel, a patterning process of a manufacturing process of a solar cell and a patterning process of a manufacturing process of a power device.

As described above, according to the present embodiments, it is possible to provide a microwave processing technique capable of uniformly processing the substrate.

As described above, according to some embodiments in the present disclosure, it is possible to uniformly process the substrate.

What is claimed is:

1. A substrate processing apparatus comprising:
a process chamber in which a substrate is processed;
a microwave generator configured to supply a microwave to the process chamber to perform a heat treatment on the substrate;
a substrate retainer configured to accommodate the substrate and a heat retainer provided above the substrate and retaining a temperature of the substrate heated by the microwave; and
a first ring plate provided on an outer circumference of the heat retainer and whose outer diameter is greater than that of the substrate.

2. The substrate processing apparatus of claim 1, wherein the heat retainer comprises a second ring plate provided with a through-hole at a central portion thereof.

3. The substrate processing apparatus of claim 1, further comprising
a third ring plate provided on an outer circumference of the first ring plate and whose outer diameter is greater than that of the first ring plate.

4. The substrate processing apparatus of claim 2, further comprising
a third ring plate provided on an outer circumference of the first ring plate and whose outer diameter is greater than that of the first ring plate.

5. The substrate processing apparatus of claim 2, further comprising
a fourth ring plate provided on an inner circumference of the second ring plate and whose inner diameter is less than that of the second ring plate.

6. The substrate processing apparatus of claim 1, wherein the heat retainer is made of a high reflectance material.

7. The substrate processing apparatus of claim 1, wherein the heat retainer is made of quartz.

8. The substrate processing apparatus of claim 1, further comprising
an additional heat retainer whose configuration is same as the heat retainer of claim 1, provided below the substrate.

9. The substrate processing apparatus of claim 2, wherein the second ring plate is provided with a support protruding radially outward from an outer circumference of the second ring plate, and the first ring plate is supported by the support.

10. The substrate processing apparatus of claim 3, wherein the first ring plate is provided with a support protruding radially outward from the outer circumference of the first ring plate, and the third ring plate is supported by the support.

11. The substrate processing apparatus of claim 4, wherein the first ring plate is provided with a support protruding radially outward from the outer circumference of the first ring plate, and the third ring plate is supported by the support.

12. The substrate processing apparatus of claim 5, wherein the second ring plate is provided with a support protruding radially inward from the inner circumference of the second ring plate, and the fourth ring plate is supported by the support.

13. The substrate processing apparatus of claim 2, wherein
the second ring plate is provided with a stepped portion obtained by cutting out an upper portion of an outer circumference of the second ring plate,
the first ring plate is provided with a stepped portion obtained by cutting out a lower portion of an inner circumference of the first ring plate, and
the second ring plate is configured to support the first ring plate by engaging the stepped portion on the outer circumference of the second ring plate and the stepped portion on the inner circumference of the first ring plate with each other.

14. The substrate processing apparatus of claim 3, wherein
the first ring plate is provided with a stepped portion obtained by cutting out an upper portion of the outer circumference of the first ring plate,
the third ring plate is provided with a stepped portion obtained by cutting out a lower portion of an inner circumference of the third ring plate, and
the first ring plate is configured to support the third ring plate by engaging the stepped portion on the outer circumference of the first ring plate and the stepped portion on the inner circumference of the third ring plate with each other.

15. The substrate processing apparatus of claim 4, wherein
the first ring plate is provided with a stepped portion obtained by cutting out an upper portion of the outer circumference of the first ring plate,
the third ring plate is provided with a stepped portion obtained by cutting out a lower portion of an inner circumference of the third ring plate, and
the first ring plate is configured to support the third ring plate by engaging the stepped portion on the outer circumference of the first ring plate and the stepped portion on the inner circumference of the third ring plate with each other.

16. The substrate processing apparatus of claim 5, wherein
the second ring plate is provided with a stepped portion obtained by cutting out an upper portion of the inner circumference of the second ring plate,
the fourth ring plate is provided with a stepped portion obtained by cutting out a lower portion of an outer circumference of the fourth ring plate, and
the second ring plate is configured to support the fourth ring plate by engaging the stepped portion on the inner circumference of the second ring plate and the stepped portion on the outer inner circumference of the fourth ring plate with each other.

17. A substrate retainer configured to accommodate a substrate and a heat retainer provided above the substrate and retaining a temperature of the substrate heated by a microwave, the substrate retainer comprising:
a ring plate provided on an outer circumference of the heat retainer and whose outer diameter is greater than that of the substrate.

18. A method of manufacturing a semiconductor device, comprising:
(a) loading a substrate into a process chamber of a substrate processing apparatus comprising:
the process chamber in which the substrate is processed;
a microwave generator configured to supply a microwave to the process chamber to perform a heat treatment on the substrate;
a substrate retainer configured to accommodate the substrate and a heat retainer provided above the substrate and retaining a temperature of the substrate heated by the microwave; and
a ring plate provided on an outer circumference of the heat retainer and whose outer diameter is greater than that of the substrate; and
(b) performing the heat treatment on the substrate by the microwave.
